(19) United States
(12) Patent Application Publication
(10) Pub. No.: US 2021/0381899 A1
(43) Pub. Date: Dec. 9, 2021

(54) Method and device for the in-situ determination of the temperature of a sample

(71) Applicant: LayTec AG, Berlin (DE)

(72) Inventors: Joerg-Thomas Zettler, Berlin (DE); Christian Kaspari, Berlin (DE)

(21) Appl. No.: 17/337,032

(22) Filed: Jun. 3, 2021

(30) Foreign Application Priority Data
Jun. 3, 2020 (DE) 10 2020 114 734.1

(51) Int. Cl. G01J 5/08; H01L 21/67

(52) U.S. Cl. CPC G01J 5/0809; H01L 22/12; H01L 21/67248

(57) ABSTRACT

The invention relates to a method and to a device for the in-situ determination of the temperature ϑ of a sample, in particular to a method and to a device for the surface-corrected determination of the temperature ϑ of a sample by means of the band-edge method.

It is provided that, for the in-situ determination of the temperature ϑ of a sample (10) when growing a layer stack (12) in a deposition system, a surface-corrected transmission spectrum T′(λ) is calculated by determining the quotient of the transmission spectrum T(λ) and a correction function K(λ), the correction function K(λ) being calculated from a determined reflection spectrum R(λ). Subsequently, the spectral position of the band-edge λ_{BE} is determined from the transmission spectrum T′(λ), and the temperature ϑ is determined from the spectral position of the band-edge λ_{BE} by means of a known dependency ϑ(λ_{BE}).

The invention relates to a method and to a device for the in-situ determination of the temperature of a sample, in particular to a method and to a device for the surface-corrected determination of the temperature of a sample by means of the band-edge method. Specifically, for improving the accuracy of the band-edge-based temperature determination for certain processes and measuring tasks, an additional reflection measurement and/or an auxiliary emissivity-corrected pyrometer have been integrated into the method and device.

### PRIOR ART

Methods for determining the temperature of a sample and temperature-measuring devices comprising a pyrometer having a suitable wavelength are generally known. Modern process pyrometers for thin-film processes have a built-in emissivity correction. This means that, in addition to the pyrometer detection, a reflection measurement is also integrated at the same wavelength. By means of this reflection measurement, the current emissivity of the layer structure is detected for correcting the pyrometer signal. The emissivity of a body at a given wavelength is the ratio of its specific emission to that of an ideal black emitter at the same temperature.

In addition to pyrometers which detect the thermal radiation of a sample at a single wavelength, multi-wavelength and spectral pyrometers have also been used for some time, which likewise regularly undergo improvements in methodology. For the in-situ determination of the temperature of a sample in a deposition system, pyrometers are particularly suitable in the high-temperature range (>400° C.). However, there are no suitable pyrometers available for the temperature range between room temperature (approx. 20° C.) and approximately 400° C., which is required in molecular beam epitaxy (MBE) for certain processes.

Furthermore, in real process environments various stray-radiation effects can occur which make an accurate measurement more difficult. In many cases, these effects can be largely suppressed by, for example, optimizing the optical set-up. There are, however, some technically relevant processes in which it is not possible to sufficiently suppress these stray-radiation effects. These include, in particular:
stray light due to the hot material sources in molecular beam epitaxy, which are usually about 100 Kelvins hotter than the sample (e.g. semiconductor substrates or other substrates or corresponding wafers) in order to thermally evaporate the layer material and to thus direct a molecular beam towards the surface of the sample; or
stray light in metal organic chemical vapor phase epitaxy (MOVPE), also called organo-metallic vapor phase epitaxy (OMVPE), which is generated by IR heaters or hot assemblies in the reactor.

For these kinds of application, temperature measurements by means of the band-edge method are known as an alternative to pyrometry. This spectral method is based on transmitted-light, reflection or scattered-light measurements, which each detect the thermal displacement of the fundamental absorption edge of the sample material. In FIG. 1 a), the transmitted-light method of band-edge sensing is illustrated. The scattered-light method of band-edge sensing is illustrated in FIG. 1 b).

Both methods of band-edge sensing were developed in the late 1980s and early 1990s. In 1987, Hellmann and Harris presented the transmitted-light method, by means of which the sample temperature of GaAs in an MBE system could be determined with a precision of ±2° C. (Hellmann and Harris, Infra-Red Transmission Spectroscopy of GaAs During Molecular Beam Epitaxy, J. Cryst. Growth, Vol. 81, 38 (1987)). Even this early work contained innovative aspects such as fiber-based optics arranged completely outside the MBE chamber, which could scan the sample by means of a translation stage.

Only a few years later, Weilmeier et al. showed that band-edge measurement also works well with diffuse reflection of the transmitted spectral component from the rough backside of the sample (scattered-light method) (Weilmeier et al., A new optical temperature measurement technique for semiconductor substrates in molecular beam epitaxy, Can. J. Phys., Vol. 69, 422 (1991)). A tungsten lamp stabilized in its output power and modulated by a chopper wheel is used for illuminating the sample in this case. Measurement artifacts (e.g. due to hot MBE sources) can be eliminated or at least reduced by the modulation of the measurement light. In this work, temperature changes of 1 K could be detected by means of the optical band-edge measurement.

The reflection method of band-edge sensing utilizes a similar set-up as the scattered-light method. The only difference is that for the reflection method both light incidence and detection are being perpendicular to the sample surface. The prerequisite is that the sample is polished on both sides, so that the light entering the sample is reflected by the backside of the sample. This light component that is not reflected by the surface passes through the sample twice in the simplest approximation, and therefore the light absorption at wavelengths below the band-edge results in a down-step in the spectral reflection signal.

All three methods of band-edge sensing have their advantages and drawbacks, so that the choice for a particular method needs to take into account the specifics of the growth system, the sample, and the process. There is a large number of methods for determining the band-edge energy E_{BE} or wavelength λ_{BE} from the spectrum. A temperature ϑ is ultimately calculated from E_{BE}(ϑ) or λ_{BE}(ϑ) by means of calibration curves or tables. By way of example, just some of these band-edge algorithms are listed here:
Linear fit of the steep rise in the diffuse reflectivity or transmission, and extrapolation to the level of a baseline signal. The point of intersection characterizes E_{BE} or λ_{BE} (Weilmeier et al.).
An extension of the above method, in which the shape of the “knee” in the spectrum is fitted using an asymptotic function. The parameters of the two asymptotes determine the point of intersection E_{BE} or λ_{BE} (Johnson et al., In situ temperature control of molecular beam epitaxy growth using band-edge thermometry, J. Vac. Sci. Technol. B, Vol. 16, 1502 (1998)).
Determination of the peak position of the first derivative of the reflection spectrum (Shen et al., Photoreflectance of GaAs and Ga_{0.82}Al_{0.18}As at elevated temperatures up to 600° C., Appl. Phys. Lett., Vol. 53, 1080 (1988)).
Fitting the “knee” in the spectrum using a suitable function. The maximum of the second derivative determines the spectral position of the “knee”. Alternatively, the numerical second derivative of the spectrum can be calculated and the range around the maximum of this second derivative can be fitted using a polynomial (Johnson, Optical Bandgap Thermometry in Molecular Beam Epitaxy, PhD thesis, University of British Columbia, 1995).

For further details on the band-edge method and its possible applications, reference is made to the corresponding technical literature (e.g. Farrer et al., Substrate temperature measurement using a commercial band-edge detection system, J. Cryst. Growth, Vol. 301-302, 88, 2007).

Since both scattered-light and reflection measurement are active measurement methods (the illumination light is actively irradiated into the process chamber of the deposition system from a light source configured therefor), the light used for the illumination can always be modulated and thus separated from stray radiation. There are, however, some technologically significant processes in which the band-edge temperature measurement cannot be utilized, or can only be utilized with relatively large measurement errors:
A) Temperature measurements during processes in which absorbing layers cover the band-edge signature of the substrate. This applies, for example, to molecular beam epitaxy of semiconductor layers having a narrow band gap (i.e. having a low-energy band-edge) on semiconductor substrates having a wider band gap (i.e. having a higher-energy band-edge).
B) Temperature measurements during processes in which transparent or only partially absorbing layers modify or deform the band-edge signature of the substrate due to interference effects. Such a situation is always relevant to molecular beam epitaxy of oxides (higher-energy band-edge in the short-wavelength spectral range) on semiconductor substrates (having a lower-energy band-edge).

### DISCLOSURE OF THE INVENTION

The object of the invention is to overcome or at least reduce the shortcomings of band-edge methods based on the prior art and to provide a solution for the insufficient accuracy of the temperature determination of a sample by means of the band-edge method in the above-mentioned technologically significant processes. In particular, a method and an associated device are provided which allow for precise determination of the sample temperature, even in applications A) and B) as described above, in which, at the present time, neither pyrometry nor prior art band-edge methods can be used in a technically feasible and economically viable manner.

The object according to the invention is achieved by a method and a device for the in-situ determination of the temperature ϑ of a sample according to the independent claims. Preferred developments are the subject of the respective dependent claims.

The invention relates to a method for the in-situ determination of the temperature ϑ of a sample when growing a layer stack in a deposition system, comprising the following steps: transmitting a first optical radiation through the sample, wherein the first optical radiation (λ) has a first intensity spectrum I₁(λ) which extends spectrally on either side of a band-edge of the sample, and measuring the radiation obtained after transmission through the sample in order to determine a transmission spectrum T(λ); irradiating a second optical radiation onto a surface of the sample to be coated, wherein the second optical radiation has a second intensity spectrum I₂(λ) and the spectral range of the second optical radiation corresponds to the spectral range of the first optical radiation, and measuring the radiation obtained after reflection from the surface in order to determine a reflection spectrum R(λ); calculating a surface-corrected transmission spectrum T′(λ) by determining the quotient of the transmission spectrum T(λ) and a correction function K(λ) according to formula (1)

T′(λ)=T(λ)/K(λ), (1)

wherein the correction function K(λ) is calculated from the reflection spectrum R(λ); determining the spectral position of the band-edge λ_{BE} from the transmission spectrum T′(λ); and determining the temperature ϑ from the spectral position of the band-edge λ_{BE} by means of a known dependency ϑ(λ_{BE}).

A sample may in particular be a substrate made of a (oxidic or non-oxidic) semiconductor material (semiconductor substrate) suitable for the band-edge method, or a corresponding wafer. The method is, however, not limited to semiconductor substrates or wafers, but instead this may be any carrier suitable for the band-edge method. A deposition system may in particular be a system for physical vapor deposition (PVD), such as a system for MBE or for vacuum evaporation.

Transmitted-light method of band-edge sensing: The first optical radiation has a first intensity spectrum I₁(λ) which extends spectrally on either side of a band-edge of the sample. In this case, the spectral width and position of the first intensity spectrum I₁(λ) has to allow the spectral position of the band-edge to be determined. Transmission through the sample means that the first optical radiation (at least with a partial range of the first intensity spectrum I₁(λ)) is transmitted through the backside, the bulk and the front side of the sample. The front side of the sample comprises a surface to be coated. In this case, the first radiation may be incident on the backside of the sample and emerge from the front side of the sample after being transmitted through the sample.

Scattered-light and reflected light methods of band-edge sensing: The radiation may, however, also be transmitted through the sample twice, such that transmission through the sample can also take place by the first radiation being incident on and emerging from the front side of the sample when the radiation is reflected or scattered on the backside of the sample (e.g. on a surface thereof) and the radiation is thus completely transmitted through the sample twice.

Preferably, the first radiation is incident on the sample such that said radiation is transmitted perpendicularly through a surface of the sample to be coated. Said radiation is then likewise transmitted perpendicularly through a layer stack applied to this surface of the sample. Said radiation may, however, also be transmitted through the surface of the sample at an angle (angle of incidence or exit angle).

After said radiation is accordingly transmitted through the sample, the first radiation has a modified transmission spectrum T(λ), wherein only the range I₁(λ>λ_{BE}) of the spectrum is transmitted through the sample because the band-edge wavelength λ_{BE} is contained in the first intensity spectrum I₁(λ). In the non-transmitted spectral range λ<λ_{BE}, due to the natural thermal radiation (black-body radiation) of the sample, a background signal is present which impacts the detection of the band-edge from the spectrum. The intensity of the first optical radiation used for being transmitted through the sample therefore has to be high enough to allow for a sufficient signal-to-noise ratio (SNR) for the band-edge detection from the spectrum. If a hot substrate carrier (the intensity of which cannot be modulated) or substrate heater radiation is used as a light source for the first intensity spectrum I₁(λ), the substrate carrier (or heater) has to be considerably hotter than the substrate (≥50 K).

According to the invention, a second optical radiation having a second intensity spectrum I₂(λ) is irradiated onto a surface of the sample to be coated. In this case, the spectral range of the second optical radiation includes at least the spectral range of the first optical radiation. The second optical radiation is used for determining a reflection spectrum R(λ) for the perpendicular or approximately perpendicular incidence (depending on the detection angle).

During processing in a deposition system, a layer stack is growing at the surface of the sample, which, due to interference effects, results in the reflection spectrum R(λ) being modified. As a result, the surface effects, i.e. the intensity modulations in the transmission spectrum T(λ) generated by interference on the layer stack, which occur in the transmission spectrum T(λ) when using the band-edge method, can be corrected.

Preferably, the first and the second radiation are therefore irradiated onto the sample such that said radiation is transmitted perpendicularly through a surface of the sample to be coated. Said radiation is then likewise transmitted perpendicularly through a layer stack applied to the surface of the sample. The second radiation can also be irradiated at an angle onto the surface of the sample to be coated, wherein the angle preferably corresponds to the angle at which the first radiation is transmitted through the layer stack applied to the surface of the sample. The two angles may also differ from one another; in this case, however, for increasing the accuracy of the method, it is preferred that the transmission spectrum T(λ) and the reflection spectrum R(λ) are adapted to one another by calculation with regard to the spectral position and form of the respective surface effects, i.e. the influence of different transmission angles may be taken into account in one spectrum or in both spectra.

For eliminating the surface effects in the transmission spectrum T(λ) by calculation, a surface-corrected transmission spectrum T′(λ) is calculated by determining the quotient of the transmission spectrum T(λ) and a correction function K(λ) according to formula (1)

T′(λ)=T(λ)/K(λ), (1)

wherein the correction function K(λ) is calculated from the reflection spectrum R(λ). The correction function K(λ) may, where necessary, also include an adaptation of the reflection spectrum R(λ) when radiation is transmitted through the surface of the sample to be coated at an angle that differs from the angle at which the first radiation is transmitted through the layer stack applied to the surface of the sample. The correction function K(λ) describes the modification of the sample transmission induced by the growing layer(s).

The spectral position of the band-edge λ_{BE} is then determined from the transmission spectrum T′(λ) and the temperature ϑ is determined from the spectral position of the band-edge λ_{BE} by means of a known dependency ϑ(λ_{BE}) in accordance with standard methods for band-edge thermometry.

### Advantages of the Invention

A method according to the invention for the in-situ determination of the temperature of a sample has some advantages over a conventional method for band-edge thermometry.

The essential difference from the prior art lies in the additional determination of the reflection spectrum R(λ) by irradiating a second optical radiation. As a result, the front side surface effects that occur in the transmission spectrum T(λ) when transmitting a first optical radiation through the sample can be removed from the transmission spectrum T(λ) by means of a correction function. As a result, the accuracy of the determination of the spectral position of the band-edge λ_{BE} and thus also the accuracy of the temperature determination is significantly improved.

An additional reflection measurement is thus utilized, with a preferably perpendicular incidence onto the sample, which extends over the same spectral range as the band-edge measurement or at least contains the spectral range of the band-edge measurement. The reflection measurement is used to correct the transmission spectrum before the band-edge analysis is started. In this case, the correction function K(λ) resulting therefrom allows to comprehensively account for the specific front side surface effects induced by the growing layer stack. In this case, the complexity of the determination of the correction function K(λ) depends on whether the applied layer(s) is/are transparent or partially absorbing in the spectral range of the band-edge measurement.

By means of the correction function K(λ) determined by means of the additional reflection measurement, according to the object, the band-edge temperature measurement can also be expanded to the above-mentioned applications A) and B), in which, at the present time, neither pyrometry nor temperature measurement in accordance with the band-edge method can be used in a technically feasible and economically viable manner. In connection with an nk(ϑ) database for the layer and substrate materials involved and with corresponding algorithms for calculating K(λ) from R(λ), an additional spectral reflection measurement therefore facilitates the real-time reconstruction of the undisturbed band-edge signatures (i.e. free of surface effects).

Preferably, the transmission spectrum T(λ) is a suitably normalized transmission spectrum Tₙₒᵣₘ(λ) and the reflection spectrum R(λ) is a suitably normalized reflection spectrum Rₙₒᵣₘ(λ). The normalized transmission spectrum Tₙₒᵣₘ(λ) can be calculated from the directly measured intensity spectrum I₁(λ) (i.e. measured without a sample) and the first intensity spectrum I₁(λ). The reflection spectrum Rₙₒᵣₘ(λ) can be calculated from an intensity spectrum I₂⁰(λ) measured on a calibration sample having known optical properties and the second intensity spectrum I₂(λ). Suitable normalization of the transmission spectrum T_{raw}(λ) and of the reflection spectrum R_{raw}(λ) can also be carried out by means of other known algorithms, e.g. by using the intensity transmitted by an as yet uncoated sample (substrate) or reflected thereby, with the optical properties of the uncoated sample (substrate) needed to be known in the temperature range of interest. By normalizing the spectra, a thin-film optical analysis of the surface effects in the reflection spectrum R(λ) is made possible, and therefore a thin-film optical correction of T(λ) by K(λ) as well.

Preferably, when applying a layer stack made up of transparent layers, the correction function K(λ) is calculated according to formula (2)

$$K ( λ ) = \frac{1 - R ( λ )}{1 - {R}_{0} ( λ )} \qquad ( 2 )$$

directly from the reflection spectrum R(λ). Here, R₀(λ) describes the reflection spectrum of the uncoated sample and R(λ) describes the reflection spectrum of the sample with the currently applied layer or the currently applied layer stack.

Preferably, when applying a layer stack made up of partially absorbing layers, the temperature ϑ is determined by means of a correction function K(λ), which is calculated by iteratively repeating steps c) to e) according to claim 1, from the reflection spectrum R(λ) and a starting value ϑ₀ for the temperature ϑ as parameters of a model for the layer structure that has already been applied, wherein a temperature determined during the iteration in step e) is used as the new temperature parameter for the model until the difference between the current value for the temperature ϑᵢ and the temperature ϑᵢ₊₁ determined thereby in step e) is below a specified threshold value (convergence criterion).

The single factor-based correction in the case of transparent layers has to be expanded here for partially transparent layers, since the increasing absorption of the growing, partially absorbing layer(s) influences the shape of the band-edge. Essentially, however, a factor-based correction is also applied here, but the correction function K(λ) is determined by means of thin-film optical simulation of the layer structure (e.g. based on a temperature-dependent nk(ϑ) database). Since the change in nk(ϑ) with the temperature ϑ is a minor effect for weakly absorbing layers, in a first approximation, the process temperature ϑ_{P} of the deposition system can be used for this purpose. Here, the procedure is preferably as follows:
Step 1: The current layer thickness dᵢ of all the layers is calculated from R(λ).
Step 2: Tᵥ is calculated using the known dᵢ and the known nkᵢ(ϑ_{P}). Here, Tᵥ is the transmission component from the substrate through the layer system on the front side.
Step 3: Determination of λ_{BE} from T′(λ)=T(λ)/K(λ). Here, the correction function is

$$K ( λ , ϑ ) = \frac{{T}_{V} ( R ( λ ) , {ϑ}_{P} )}{1 - {R}_{0} ( λ )} \qquad ( 3 )$$

Step 4: Determination of ϑ(λ_{BE}) from λ_{BE}.

Preferably, the dependency ϑ(λ_{BE}) for a specific substrate material (sample material) and the substrate thickness d is at least approximately derived from a reference database. This database can be obtained in advance by means of appropriate measurements on suitable reference substrates. For example, the dependency between the temperature of the substrate and the spectral position of the band-edge can be measured outside a deposition system using an optical set-up with calibrated temperature control. For more details regarding this topic, reference is made in particular to the relevant technical literature relating to the band-edge method that has already been cited above. The method described here for improving the accuracy of ϑ₀(T(λ))→ϑ₁(T′(λ)) can, if necessary, also be applied iteratively by calculating Tᵥ(R(λ)) again using ϑ₁, etc.

For unknown samples or not precisely known substrate thicknesses d (also specifically for samples produced by means of wafer bonding having considerably lower thicknesses of the relevant semiconductor material, e.g. 100 μm thick, bonded GaAs compared to GaAs wafers that are several 100 μm thick), a new calibration table would have to be generated each time, which is time-consuming. To simplify this step, an additional measurement using an emissivity-corrected pyrometer can be used. To do this, an emissivity-corrected pyrometric measurement is carried out for a certain number of different temperatures in a temperature range that is covered by both measurement methods (known as a common temperature range Δϑ, FIG. 7). The known calibration curve λ_{BE}(ϑ) can then be suitably scaled, such that it matches the pyrometric measurement in the common temperature range M. This is possible since the progression of the dependency ϑ(λ_{BE}) generally corresponds to a smooth function having an almost linear increase in the direction of increasing wavelengths λ. A corresponding scaling factor for ϑ(λ_{BE}) can therefore already be derived from the curve λ_{BE}^{Ref}(ϑ) of a reference substrate of another thickness by pyrometric reference measurement in the common temperature range Δϑ. λ_{BE}(ϑ)=λ_{BE}^{Ref}(ϑ)+Δλ_{BE}.

Preferably, a dependency ϑ_{d1}(λ_{BE}) known for a predetermined sample thickness d₁ is used for determining the dependency ϑ_{d2}(λ_{BE}) for a sample thickness d₂ that differs therefrom, by the dependency λ_{BE}(ϑ) being ascertained using an emissivity-corrected pyrometer in a temperature range Δϑ which is covered both by the pyrometer and the band-edge based temperature sensing method, and by the dependency ϑ_{d2}(λ_{BE}) being accordingly adapted in the temperature range outside Δϑ, which is only covered by the band-edge based temperature sensing method according to the invention, from the progression of the known dependency ϑ_{d1}(λ_{BE}). On this basis, Δλ_{BE} is determined. Where necessary, more complex corrections (compared to the simple offset Δλ_{BE}) can be derived from the precise knowledge of the substrate temperature in the common temperature range Δϑ.

The method described above for unknown samples or wafer thicknesses can be applied in the same way to samples and wafers having unknown or differing doping level. Here, the position of the measured band-edge is slightly modified by the doping level. The known calibration curve for the temperature determination by means of the band-edge method can also be accordingly corrected here using a comparative measurement with an emissivity-corrected pyrometer.

Another aspect of the invention relates to a device for carrying out a method according to the invention, comprising: a second radiation source, configured to irradiate the second optical radiation onto the surface of the sample to be coated; a spectrometer, configured to determine the reflection spectrum R(λ); and an electronic data-processing apparatus, configured to carry out method steps c) to e) from claim 1 using the transmission spectrum T(λ) and the reflection spectrum R(λ) to determine the temperature ϑ.

A device according to the invention is designed for carrying out a method according to the invention. In this respect, each of the features mentioned in the description with regard to the method can be implemented as a corresponding device feature. A second radiation source, a spectrometer and an electronic data-processing apparatus are in particular considered to be items that are essential device features. Here, the electronic data-processing apparatus is preferably configured in particular to automatically carry out method steps c) to e). As a result, it is in particular possible to implement the iterative method in the case of partially absorbing layers. Moreover, the electronic data-processing apparatus can also be configured to automatically carry out additional or all remaining method steps according to the invention.

Preferably, a device according to the invention further comprises a first radiation source, configured to transmit the first optical radiation through the sample. Here, a first radiation source is understood to be an additional component of the device which is designed to emit the first optical radiation. However, the first optical radiation required for carrying out a method according to the invention does not necessarily need to originate from such a first radiation source belonging to the device. The radiation source may also be external radiation generated inside or outside a deposition system (e.g. radiation coming from the sample heater in the chamber). In this case, the corresponding radiation source is not part of a device according to the invention.

Further preferred embodiments of the invention follow from the features set out in the dependent claims.

The different embodiments of the invention set out in this application are advantageously able to be combined with one another unless otherwise specified.

### DRAWINGS

Exemplary embodiments of the invention are explained in greater detail with reference to the drawings and the following description. In the drawings:

FIG. 1 shows schematic views of a method for determining the temperature of a sample by means of the band-edge method according to the prior art,

FIG. 2 shows a schematic view of a first embodiment (sample heater as light source) of a method according to the invention for determining the temperature of a sample by means of the band-edge method,

FIG. 3 shows a schematic view of a second embodiment (having an additional light source) of a method according to the invention for determining the temperature of a sample by means of the band-edge method,

FIG. 4 shows a simulated modification of the band-edge signature depending on the thickness of a layer stack,

FIG. 5 shows a simulated dependency of the correction function K(λ) depending on the thickness of a layer stack,

FIG. 6 shows a schematic view of a method according to the invention for determining the correction function K(λ) when growing a layer stack made up of partially absorbing layers, and

FIG. 7 shows a calibration specification for deriving the calibration curve of a sample of unknown sample thickness d by means of emissivity-corrected pyrometry.

### EMBODIMENTS OF THE INVENTION

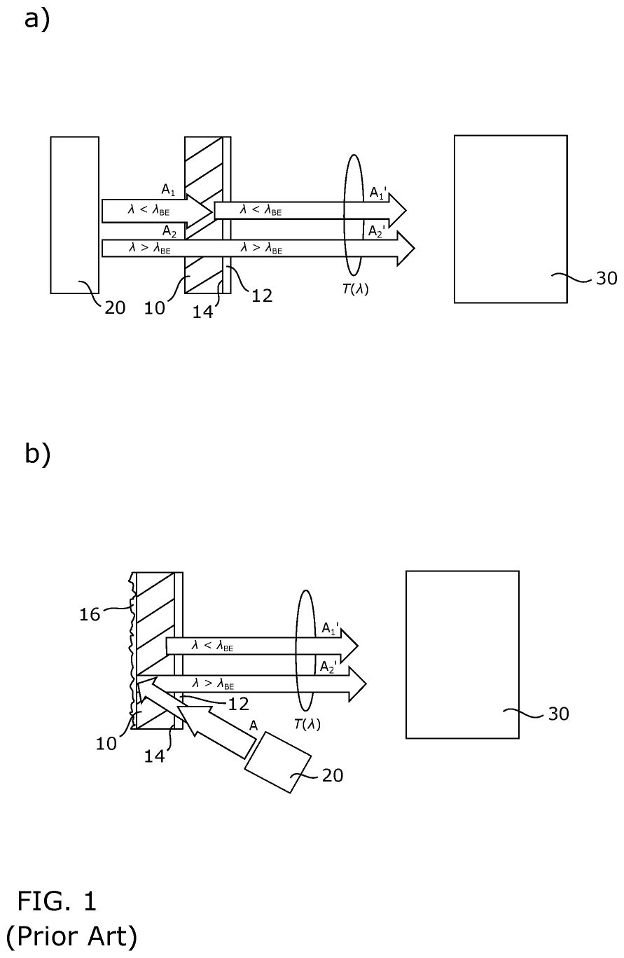

FIG. 1 shows schematic views of a method for determining the temperature ϑ of a sample 10 by means of the band-edge method according to the prior art. In particular, FIG. 1 a) shows a method in which the sample heater of the deposition system is used as an external first radiation source 20 for a first optical radiation A. The first optical radiation A is transmitted through the sample 10, wherein the first optical radiation A has a first intensity spectrum I₁(λ) which extends spectrally on either side of a band-edge (BE) of the sample 10, and the radiation A′ obtained after transmission through the sample 10 is measured in order to determine a transmission spectrum T(λ). The sample 10 may in particular be a semiconductor substrate. A layer stack 12 is applied to the front side 14 of the sample 10. This embodiment is also referred to as a transmitted-light configuration.

The transmission spectrum T(λ) measured by the spectrometer 30 is composed of several components. These are a component A′₁ having wavelengths λ<λ_{BE}, a component A′₂ having wavelengths λ>λ_{BE}, and an additional interference component C′, which originates from a thermal MBE source, for example. The radiation A₁ having wavelengths λ<λ_{BE} is absorbed during transmission through the sample 10. However, the sample 10 likewise emits corresponding thermal radiation, such that this wavelength range appears in the measured transmission spectrum T(λ) as an interference signal in the background. The radiation A₂ having wavelengths λ>λ_{BE} is largely transmitted during transmission through the sample 10. In the transmission spectrum T(λ), the band-edge characteristic used for the temperature determination is thus essentially apparent as a transition region between the spectral components A′₁ and A′₂, the background radiation C′ being superimposed on the spectrum.

FIG. 1 b) shows an alternative method in which an additional first radiation source 20 is used for generating a first optical radiation A. The method corresponds to that described with regard to FIG. 1 a), but the first radiation A is first reflected or scattered by the backside 16 of the sample 10. Preferably, scattering takes place at locations of surface roughness, such that the measurement of the radiation A′ obtained after transmission through the sample 10 is using a scattered component which has been transmitted perpendicularly through the surface 14 of the sample 10 to be coated. This embodiment is also referred to as a scattered-light configuration.

For both embodiments, in the band-edge method, the spectral position of the band-edge λ_{BE} is first determined from the transmission spectrum T(λ). The temperature ϑ of the sample 10 is subsequently determined therefrom by means of a known dependency ϑ(λ_{BE}). A significant drawback of the prior art is, however, that, due to the layer stack 12, surface effects are superimposed on the transmission spectrum T(λ), which make it difficult to accurately determine the spectral position of the band-edge λ_{BE}. These contributions from the growing layers are usually ignored in the prior art and result in temperature errors.

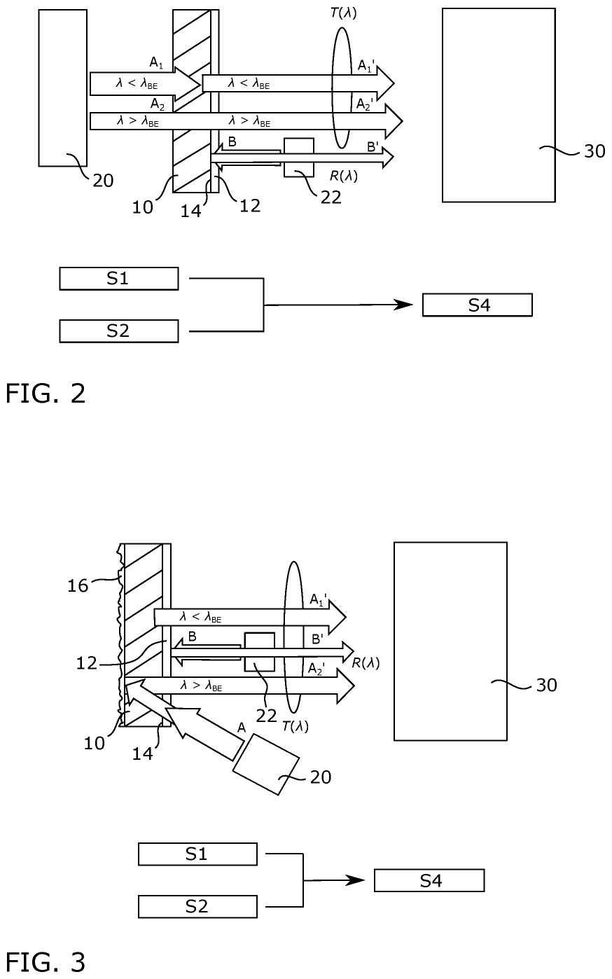

FIG. 2 shows a schematic view of a first embodiment (sample heater as light source) of a method according to the invention for determining the temperature ϑ of a sample 10 by means of the band-edge method. This embodiment is based on the relationships described in FIG. 1 a). Therefore, the reference signs and their allocation apply accordingly. However, in addition, a second optical radiation B is irradiated onto a surface 14 of the sample 10 to be coated, wherein the second optical radiation B has a second intensity spectrum I₂(λ) and the spectral range of the second optical radiation B includes the spectral range of the first optical radiation A, and the radiation B′ obtained after reflection from the surface is measured in order to determine S2 a reflection spectrum R(λ). Here, the second optical radiation B is emitted by a second radiation source 22, the radiation preferably being incident onto the sample 10 perpendicularly to the surface on the front side 14 of the sample 10. A determination S4 of the temperature ϑ from the spectral position of the band-edge λ_{BE} by means of a known dependency ϑ(λ_{BE}) thus takes place according to the invention by means of the determination S1 of a transmission spectrum T(λ) and the determination S2 of a reflection spectrum R(λ).

FIG. 3 shows a schematic view of a second embodiment (having an additional light source) of a method according to the invention for determining the temperature 7, of a sample 10 by means of the band-edge method. This embodiment is based on the relationships described in FIG. 1 b). Therefore, the reference signs and their allocation apply accordingly. Similarly to the embodiment according to FIG. 2, here too, a second optical radiation B is additionally irradiated onto a surface 14 of the sample 10 to be coated, wherein the second optical radiation B has a second intensity spectrum I₂(λ) and the spectral range of the second optical radiation B includes the spectral range of the first optical radiation A, and the radiation B′ obtained after reflection from the surface is measured in order to determine S2 a reflection spectrum R(λ). Reference is made to the description of FIG. 2 in this regard.

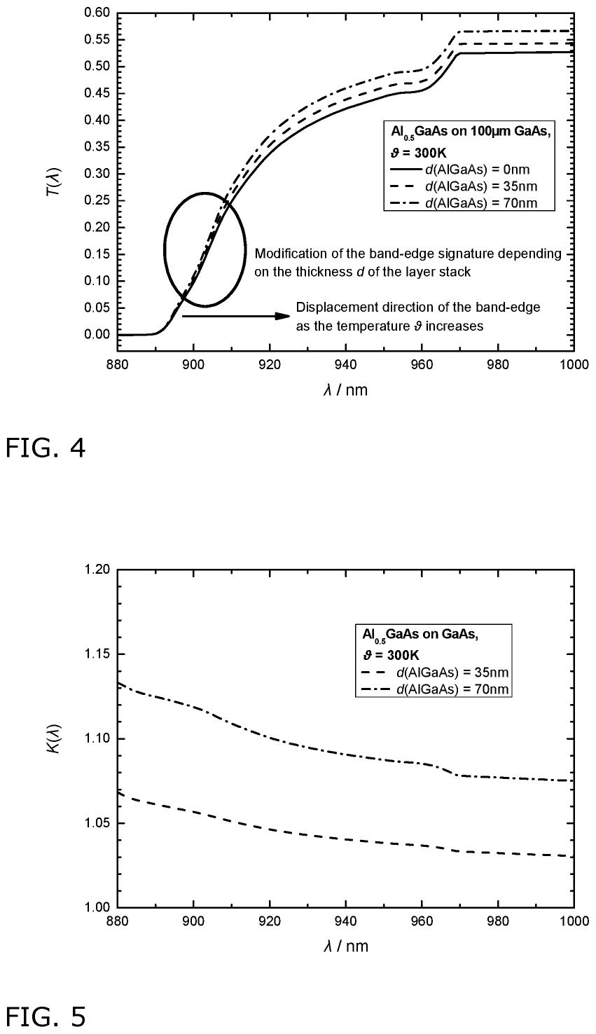

FIG. 4 shows a simulated modification of the band-edge signature depending on the thickness of a layer stack 12. In the simulation, layers of Al_{0.5}GaAs of different thicknesses, which would visibly deform the band-edge signature of the sample (solid line) and would result in a distorted temperature measurement, were applied to a 100 μm thick GaAs sample (where ϑ=300 K) which was polished on both sides. The graph also indicates in what direction the band-edge signature would shift as the temperature increases ϑ.

FIG. 5 shows a simulated dependency of the correction function K(λ) depending on the thickness of a layer stack 12. In the simulation, a layer system composed of Al_{0.5}GaAs on GaAs (where ϑ=300K) was compared for two different thicknesses of the Al_{0.5}GaAs layer. The correction function K(λ) was calculated according to formula (2)

$$K ( λ ) = \frac{1 - R ( λ )}{1 - {R}_{0} ( λ )} \qquad ( 2 )$$

from the reflection spectrum R(λ), wherein the divisor contains the reflection spectrum R₀(λ) of the sample before the deposition.

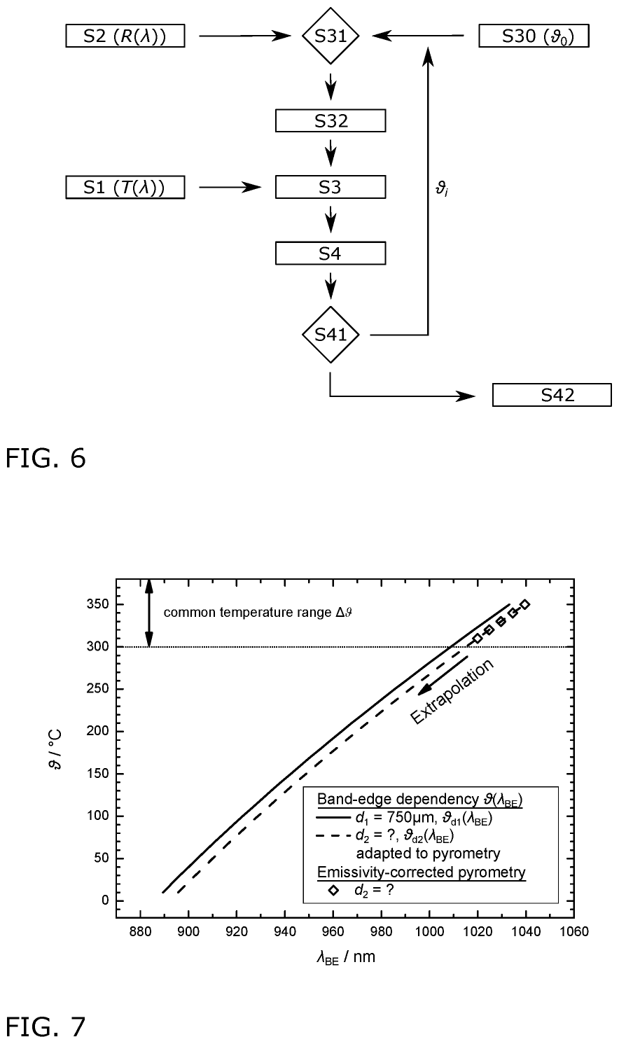

FIG. 6 shows a schematic view of a method according to the invention for determining the correction function K(λ) when growing a layer stack 12 made up of partially absorbing layers. This is a method in which, by iteratively repeating steps c) to e) according to claim 1, the temperature ϑ is calculated by means of a correction function K(λ) from the reflection spectrum R(λ) and a starting value ϑ₀ for the temperature ϑ as parameters of a model for the layer stack 12 that has already been applied, wherein a temperature determined during the iteration in step e) is used as the new temperature parameter for the model until the difference between the current value for the temperature ϑᵢ and the temperature ϑᵢ₊₁ determined thereby in step e) is below a specified threshold value. Specifically, a determination S2 of a reflection spectrum R(λ) according to the invention and a determination S30 of a starting value ϑ₀ are first carried out. Using these parameters, an adaptation S31 of the model for the already applied layer stack 12 is carried out. By means of the model, a calculation S32 of a correction function K(λ) is subsequently carried out. A calculation S3 of a surface-corrected transmission spectrum T′(λ) requires the determination S1 of a transmission spectrum T(λ). A determination S4 of the temperature ϑᵢ is then carried out by means of the conventional band-edge method.

A comparison S41 of the difference |ϑᵢ₊₁−ϑᵢ| with a specified threshold value is also carried out for the iteration. If the difference is greater than the threshold value, another adaptation S31 of the model is carried out for the already applied layer stack 12, the current value for the temperature ϑᵢ₊₁ being used as a new temperature parameter for the model. In another iteration step, the corresponding steps are then cycled through again, but another determination S1 of the transmission spectrum T(λ) does not take place within the iteration loop. This determination is transferred from the preceding cycle unchanged for the calculation S3 of an iteratively improved, surface-corrected transmission spectrum T′(λ). If, during the comparison S41 of the difference |εᵢ₊₁−ϑᵢ|, the difference is ultimately less than the threshold value, an output S42 of the temperature ϑᵢ₊₁ is made as the final result of the temperature measurement.

FIG. 7 shows a calibration specification for deriving the calibration curve of a sample 10 of unknown thickness d by means of emissivity-corrected pyrometry. The dependency ϑ_{d1}(λ_{BE}) known for a predetermined sample thickness d₁ is used here for determining the dependency ϑ_{d2} (λ_{BE}) for a sample thickness d₂ that differs therefrom, by the dependency λ_{BE}(S) being ascertained using an emissivity-corrected pyrometer in a temperature range Δϑ which is covered both by the pyrometer and the method, and by the dependency ϑ_{d2}(λ_{BE}) being accordingly adapted in the temperature range outside Δϑ, which is only covered by the method according to the invention, from the progression of the known dependency ϑ_{d1}(λ_{BE}). From a known calibration curve for a certain sample thickness ϑ_{d1}=750 μm), an analogous calibration curve can be derived thereby for a sample 10 that is made of the same material but does not have a precisely known thickness d₂. To do this, an emissivity-corrected pyrometric measurement is carried out for a set of different temperatures in a temperature range M (known as the common temperature range) in which both a band-edge measurement and a pyrometric measurement (i.e. a sufficient quantity of thermal photons is emitted) are possible. The calibration curve can then be modified or extrapolated (e.g. by offset shift or other suitable methods) such that it matches the pyrometric measurement in the common temperature range.

### LIST OF REFERENCE SIGNS

10 Sample
12 Layer stack
14 Front side
16 Backside
20 First radiation source
22 Second radiation source
30 Spectrometer
S1 Determination of a transmission spectrum T(λ)
S2 Determination of a reflection spectrum R(λ)
S30 Determination of a starting value ϑ₀
S31 Adaptation of the model for the already applied layer stack
S32 Calculation of a correction function K(λ)
S3 Calculation of a surface-corrected transmission spectrum T′(λ)
S4 Determination of the temperature ϑ and ϑᵢ (with iterative calculation)
S41 Comparison of the difference |ϑᵢ₊₁−ϑᵢ| with a specified threshold value
S42 Output of the temperature ϑ
A, A′ First optical radiation
B, B′ Second optical radiation
d Sample thickness
BE Band-edge
ϑ Temperature of the sample
ϑ_{P} Process temperature

What is claimed is:

1. A method for the in-situ determination of the temperature ϑ of a sample when growing a layer stack in a deposition system, comprising the following steps:
a) transmitting a first optical radiation through the sample, wherein the first optical radiation has a first intensity spectrum I₁(λ) which extends spectrally on either side of a band-edge of the sample, and measuring the radiation obtained after transmission through the sample in order to determine a transmission spectrum T(λ);
b) irradiating a second optical radiation onto a surface of the sample to be coated, wherein the second optical radiation has a second intensity spectrum I₂(λ) and the spectral range of the second optical radiation includes the spectral range of the first optical radiation, and measuring the radiation obtained after reflection from the surface in order to determine a reflection spectrum R(λ);
c) calculating a surface-corrected transmission spectrum T′(λ) by determining the quotient of the transmission spectrum T(λ) and a correction function K(λ) according to formula (1)
T′(λ)=T(λ)/K(λ), (1)
wherein the correction function K(λ) is calculated from the reflection spectrum R(λ);
d) determining the spectral position of the band-edge λ_{BE} from the transmission spectrum T′(λ); and
e) determining the temperature ϑ from the spectral position of the band-edge λ_{BE} by means of a known dependency ϑ(GIBE).

2. The method of claim 1, wherein the transmission spectrum T(λ) is a normalized transmission spectrum Tₙₒᵣₘ(λ) and the reflection spectrum R(λ) is a normalized reflection spectrum Rₙₒᵣₘ(λ).

3. The method of claim 1, wherein, when growing a layer stack made up of transparent layers, the correction function K(λ) is calculated according to formula (2)
$$K ( λ ) = \frac{1 - R ( λ )}{1 - {R}_{0} ( λ )} \qquad ( 2 )$$
from the reflection spectrum R(λ), wherein the divisor contains the reflection spectrum R₀(λ) of the sample before the deposition.

4. The method of claim 1, wherein, when growing a layer stack made up of partially absorbing layers, the temperature ϑ is determined by means of a correction function K(λ), which is calculated by iteratively repeating steps c) to e), from the reflection spectrum R(λ) and a starting value ϑ₀ for the temperature ϑ as parameters of a model for the layer stack that has already been applied, wherein a temperature determined during the iteration in step e) is used as the new temperature parameter for the model until the difference between the current value for the temperature ϑᵢ and the temperature ϑᵢ₊₁ determined thereby in step e) is below a specified threshold value.

5. The method of claim 4, wherein the starting value ϑ₀ for the temperature ϑ is the process temperature ϑ_{P} of the deposition system, associated with the reflection spectrum R(λ).

6. The method of claim 1, wherein the dependency ϑ(λ_{BE}) is at least approximately derived from a reference database in accordance with the material of the sample and the sample thickness d.

7. The method of claim 1, wherein the dependency ϑ_{d1}(λ_{BE}) known for a predetermined sample thickness d₁ is used for determining the dependency ϑ_{d2} (λ_{BE}) for a sample thickness d₂ that differs therefrom, by the dependency λ_{BE}(ϑ) being ascertained using an emissivity-corrected pyrometer in a temperature range Δϑ which is covered both by the pyrometer and the method, and by the dependency ϑ_{d2}(λ_{BE}) being accordingly adapted in the temperature range outside Δϑ, which is only covered by the method according to the invention, from the progression of the known dependency ϑ_{d1}(λ_{BE}).

8. The method of claim 7, wherein, proceeding from a known dependency ϑ(λ_{BE}) for known sample doping level, a corresponding dependency is ascertained for a sample having differing or unknown doping level.

9. A device for carrying out the method of claim 1, comprising:
a) a second radiation source, configured to irradiate the second optical radiation onto the surface of the sample to be coated;
b) a spectrometer, configured to determine the transmission spectrum T(λ) and a reflection spectrum R(λ); and
c) an electronic data-processing apparatus, configured to carry out method steps c) to e) from claim 1 using the transmission spectrum T(λ) and the reflection spectrum R(λ) to determine the temperature ϑ.

10. The device according to claim 9, further comprising a first radiation source, configured to transmit the first optical radiation through the sample.
